(19) United States
(12) Patent Application Publication
(10) Pub. No.: US 2026/0326552 A1
(43) Pub. Date: Oct. 22, 2026

(54) Light Emitting Device, Motor Vehicle Component, Motor Vehicle and Method to Manufacture a Light Emitting Device

(71) Applicant: Motherson Innovations Company Limited, London (GB)

(72) Inventor: Thomas Agung NUGRAHA, Stuttgart (DE)

(21) Appl. No.: 19/105,862

(22) PCT Filed: Oct. 25, 2023
(86) PCT No.: PCT/EP2023/079793

§ 371 Date: Feb. 24, 2025

Related U.S. Application Data
(60) Provisional application No. 63/429,641, filed on Dec. 2, 2022.

(30) Foreign Application Priority Data
Oct. 25, 2022 (DE) 10 2022 128 119.1

(51) Int. Cl. B60K 35/22; H10H 29/01; H10H 29/02; H10H 29/85; H10H 29/852; H10H 29/856

(52) U.S. Cl. CPC B60K 35/22; H10H 29/012; H10H 29/02; H10H 29/0362; H10H 29/8508; H10H 29/852; H10H 29/856; B60K 2360/1438; B60K 2360/1523; B60K 2360/23; B60K 2360/332; B60K 2360/42; B60K 2360/48

(57) ABSTRACT

The present disclosure relates to a LED light emitting device with a layer stack and one or more LEDs attached to a base layer wherein printed electronics are attached to the base layer providing at least signal and power lines to operate the one or more LEDs; to a motor vehicle component comprising such LED light emitting device; to a motor vehicle with such a motor vehicle component; and to a method to manufacture such LED light emitting device.

### CROSS-REFERENCE TO RELATED APPLICATIONS

This application is a national-stage entry of PCT/EP2023/079793, filed on Oct. 25, 2023, which claims priority to U.S. Provisional Patent Application No. 63/429,641, filed on Dec. 2, 2022 and German Patent Application No. DE 10 2022 128 119.1, filed on Oct. 25, 2022, each of which are incorporated herein by reference in their entirety.

### TECHNICAL FIELD

The present disclosure relates to a light emitting device, in particular that includes a reflector, and especially, an LED (Light Emitting Diode) illuminated reflector implemented on a vehicle. The present invention is also directed to a motor vehicle part comprising such a light emitting device, a motor vehicle with such a motor vehicle part and a method to manufacture such light emitting device.

### BACKGROUND

Known LED light emitting devices, such as LED displays, with a layer stack comprise a large number of layers on top of a substrate for providing light emission and optional touch panel functionality. The high number of required layers increases the complexity of the layer stack and therefore complicates the manufacturing conditions. Each layer has to be produced, one after the other, in order to achieve a satisfactory yield of functioning layer stacks. The devices are commonly operated by a printed circuit board (PCB), where the LEDs are attached to, in particular an upper surface of a printed circuit board. The printed circuit is a further component within the layer stack further increasing its complexity.

The PCB might be arranged under a reflector layer, which is the simplest solution. However, apertures and/or holes are required for each LED and high light losses are cause due to the LED light emission is obstructed by the reflector on the side of the LEDs. In case a PCB and/or the before mentioned is arranged on top of the reflector, the light emission is improved but the PCBs need to be uniquely cut setting high challenges on manufacturing and integration. In case a PCB and/or the before mentioned PCB and the reflector are in in the same layer, in particular arranged in the same layer, both PCB and reflector need to have a unique cut and even more challenges on manufacturing and integration occur.

US 2011/0198628 refers to a multi-chip LED package, which includes a PCB having a tapered aperture and/or hole and a circuit interconnection line on a surface of the PCB. An inclined surface of each aperture and/or hole is used as a reflection plate reflecting light emitted by an LED chip located in the aperture and/or hole. Each LED chip is directly bonded to a metal base for radiating heat.

### SUMMARY

The present disclosure provides and/or it is an object of the present disclosure to provide a light emitting device having a layer stack with a reduced number of layers to ease manufacturing and to obtain an improved production yield due to the reduced number of layers.

The present invention is directed to a light emitting device with a layer stack comprising:
a base layer with a reflective surface,
one or more LEDs attached to the reflective surface, base layer, and
wherein the base layer comprises or is provided with printed electronics for providing a power lines to operate an LED.

In one embodiment, the device further comprises at least one encapsulation layer, with the one or more LEDs and/or the base layer being covered by the encapsulation layer.

In one embodiment, the electronics are printed on top of the reflective surface of the base layer directed towards the one or more LEDs, with preferably the printed electronics (comprising conductive ink.

In a further embodiment, the one or more LEDs, a driver IC and/or at least one electronic component are attached and electrically connected to the printed electronics of the base layer via conductive glue, or an anisotropic or isotopic adhesive, or a low temperature solder paste.

In a further embodiment, the base layer and the printed electronics are covered by an overcoat protective layer in areas not covered by the one or more LEDs, the driver IC and/or the at least one electronic component or the conductive glue, the anisotropic or isotopic adhesive or the temperature solder paste.

In a further embodiment, the base layer has a second side directed away from the one or more LEDs, and a printed capacitive touch sensor pattern is provided on top of the second side, preferably by printing.

In a further embodiment, the one or more LEDs comprise first LEDs in form of top or top/side emitting LEDs with an average emission direction (ED) away from the base layer and/or second LEDs in form of bottom emitting LEDs, wherein the base layer comprises an aperture in an area of the base layer covered by a bottom emitting LED and the bottom emitting LED emits light in the average emission direction (ED) through the aperture of the base layer.

In a further embodiment, the stack further comprises a diffuser layer, in particular comprising translucent material, a touch sensor electronic layer, preferably in case no printed capacitive touch sensor pattern is provided, a carrier layer, and/or a protection or cosmetic layer. In one embodiment, the carrier layer is provided with injection molded electronics or glued electronics, with the electronics preferably comprising touch sensors on top of the encapsulation layer or on top of the diffuser layer.

In a further embodiment, the device provides a display device and/or a touch screen.

In a further aspect the present invention is directed to a motor vehicle component comprising at least one device provided herein, wherein preferably the motor vehicle component comprises a rear view device, a dashboard and/or an interior lining.

In one embodiment, the protection or cosmetic layer and/or the surface geometry of the first and/or second surface of the base layer is suited to be adapted to the remaining motor vehicle component and/or the surrounding thereof.

In a still further aspect, the present invention is directed to a motor vehicle comprising at least one motor vehicle component provided herein.

In a still further aspect, the present invention is directed to a method to manufacture a light emitting device provided herein, comprising the steps of providing a base layer with a reflective surface; integrating printed electronics to the base layer providing at least signal and power lines to operate the one or more LEDs; and attaching one or more LEDs on the reflective surface of the base layer.

In one embodiment, the one or more LEDs and/or base layer are covered by an encapsulation layer, and wherein the integration step comprises printing the electronics on the reflective surface of the base layer, preferably in form of screen printing or gravure printing, and/or preferably with multiple ink materials and/or multiple printing steps. The integration step may comprises one or more heat and/or UV curing steps.

In one embodiment, the base layer is formed with a curved reflective surface and/or second surface and/or is cut into shape.

In a further embodiment, in case of using one or more bottom emitting LEDs, a structuring step for providing an aperture within the base layer in each area, where a bottom emitting LED is attached, is carried out prior to the attaching step.

In a further embodiment, each aperture is provided by etching or punching and/or is filled with material of an encapsulation layer to provide a smooth surface for the LEDs to be applied.

In a still further embodiment, the method comprises a step of covering the printed electronics with an overcoat protective layer, in particular in areas not covered by the one or more LEDs or conductive glue, before applying the encapsulation layer.

In a still further embodiment, the attaching step includes an adhesive and/or solder place extraction and/or a heat treatment.

In a still further embodiment, the method comprises a step of applying a diffusor layer, an electronic touch sensor layer, a carrier layer and/or a protection or cosmetic layer on the encapsulating layer.

In a still further embodiment, the method comprises embedding a touch sensor function to the stack, comprising printing a capacitive touch sensor pattern on the second side of the base layer, or applying the touch sensor electronic layer, preferably on the diffuser layer (23) and/or on the reflective surface of the base layer.

### BRIEF DESCRIPTION OF THE DRAWINGS

Further advantages and features of the present disclosure will become apparent from the following description and the accompanying drawings, to which reference is made. In which are shown:

FIG. 1A is a schematic view of a LED light emitting device according to a first embodiment of the present disclosure for top/side emitting LEDs;

FIG. 1B is a schematic view of a LED light emitting device according to a second embodiment of the present disclosure for top/side emitting LEDs and with printed capacitive touch sensor pattern;

FIG. 2A is a schematic view of a LED light emitting device according to a third embodiment of the present disclosure for bottom emitting LEDs;

FIG. 2B is a schematic view of a LED light emitting device according to a fourth embodiment of the present disclosure for bottom emitting LEDs with printed capacitive touch sensor pattern;

FIG. 3 is a schematic view of the motor vehicle comprising one or more LED light emitting device as shown in FIG. 1A; and

FIG. 4a is a schematic view of a variation to the LED light emitting device 1 according to a fifth embodiment of the present disclosure for top emitting LEDs in a side view; and

FIG. 4b illustrates a fifth embodiment of the present disclosure for top emitting LEDs from FIG. 4a in a top view; and

FIG. 5 illustrates an embodiment of a method according to the present disclosure.

FIG. 5A illustrates a cross-sectional view of a sixth embodiment of the present disclosure;

FIG. 5B illustrates an expanded view of the LED light emitting device of FIG. 5A.

FIG. 5C illustrates a plan view of the LED light emitting device of FIGS. 5A and 5B.

FIG. 6A illustrates a cross-sectional view of a seventh embodiment of the present disclosure;

FIG. 6B illustrates an expanded view of the LED light emitting device of FIG. 6A.

FIG. 6C illustrates a plan view of the LED light emitting device of FIGS. 6A and 6B.

FIG. 7A illustrates a cross-sectional view of an eighth embodiment of the present disclosure;

FIG. 7B is an expanded view of the LED light emitting device of FIG. 7A.

FIG. 7C is a bottom view of the LED light emitting device of FIGS. 7A and 7B.

FIG. 8A is a cross-sectional view of a ninth embodiment of the present disclosure;

FIG. 8B is an expanded view of the LED light emitting device of FIG. 8A.

FIG. 8C is a bottom view of the LED light emitting device of FIGS. 8A and 8B.

### DETAILED DESCRIPTION OF THE INVENTION

Reference will now be made in detail to presently preferred compositions, embodiments and methods of the present disclosure, which constitute the best modes of practicing the present disclosure presently known to the inventors. The figures are not necessarily to scale. However, it is to be understood that the disclosed embodiments are merely exemplary of the present disclosure that may be embodied in various and alternative forms. Therefore, specific details disclosed herein are not to be interpreted as limiting, but merely as a representative basis for any aspect of the present disclosure and/or as a representative basis for teaching one skilled in the art to variously employ the present disclosure.

It is also to be understood that this present disclosure is not limited to the specific embodiments and methods described below, as specific components and/or conditions may, of course, vary. Furthermore, the terminology used herein is used only for the purpose of describing particular embodiments of the present disclosure and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The present invention is directed to a light emitting device with a layer stack comprising a base layer with a reflective surface, one or more LEDs attached to the reflective surface, base layer, and wherein the base layer comprises or is provided with printed electronics for providing a power lines to operate an LED.

Thus, a light emitting device, e.g. an LED matrix display, is provided, which has a layer stack with a reduced number of layers to ease manufacturing and to obtain an improved production yield due to the reduced number of layers. Said layer stack comprises one or more LEDs attached to a base layer having a reflective surface, where the base layer comprises or includes printed electronics as part of the base layer providing at least signal and/or power lines to operate the one or more LEDs.

In this context, reflective surface is understood to mean that the base layer has a reflective side which reflects the light emitted by the LEDs in one main direction. This reflection does not necessarily have to occur on the surface of the base layer. Reflective surface is therefore understood to be the side of the base layer from which the light is essentially reflected away.

In addition to the power lines, the base layer can also feature other current-carrying printed electronics. For example, the base layer can also include signal lines. In this context, signal lines are understood to mean both control lines and data lines.

In electrical engineering, a control line is a connection between a transmitter and receiver that is implemented, for example, via an electrically conductive connection. Via this connection, mainly via a logical state (0 or 1), the receiver is switched to another operating mode or state and/or a certain process is started or stopped. The communication normally takes place only unidirectionally, namely from the transmitter to the receiver. Control lines are mainly found in integrated circuits (ICs). Known digital inputs of an IC that are connected to a control line are e.g. Chipselect, Reset or Enable.

In information and communication technology, a data line is a physical transmission medium, such as an electrical connection, of a connection between a transmitter and receiver or the connection as such. This connection is mainly used to transmit information (data), which is then processed further. A data line usually allows bidirectional communication, i.e. the sender becomes the receiver and vice versa. In microcontrollers very often only unidirectional data lines are used. An example of this is the Serial Peripheral Interface (SPI), which has one unidirectional data line each for the send and receive direction. The term data line is also used for integrated circuits (ICs).

The inventive light emitting device may comprise at least one encapsulation layer, with the one or more LEDs and/or the base layer being covered by the encapsulation layer. The encapsulation layer can be made of any transparent material known to the skilled person. Preferably, the encapsulation layer is translucent, which means that it is permeable to the light emitted by the LEDs. It is also possible that the encapsulation layer is opaque. Furthermore, it is possible that the encapsulation layer contains a dye. By means of a dye, the color of the emitted light of the LEDs can be adjusted.

The layer stack forms the light emitting device, where the LEDs are the light emitting centers within the light emitting device. There might be one single LED within the layer stack. In other embodiments there might be several LEDs arranged within the layer stack. The multiple LEDs might be arranged in a 2-dimensional array, where the LEDs are distributed along the base layer in a symmetric or non-symmetric manner. The layer stack may comprise additional layers such as a diffuser layer on top of the encapsulation layer, a carrier layer with injection molded electronics or glued electronics with touch sensors on top of the encapsulation layer or on top of the diffuser layer. The electronics with touch sensor might be applied as separate layer together with a carrier layer. Onto the diffuser or carrier layer there might be another protection layer, e.g. providing mechanical stability and resistance to the environment or a cosmetic surface to provide a certain appearance of the LED light emitting device. The diffuser (also called a light diffuser or optical diffuser) layer may be made of any material that diffuses or scatters light in some manner to transmit soft light in transmission through the diffuser layer. Diffusers may use translucent material, for example ground glass, opal glass or greyed glass. The encapsulation layer may be any suitable transparent layer which passivates the LEDs, the printed electronics and/or the base layer, e.g. silicon nitride etc.

The base layer according to the present disclosure fulfills a double purpose, on one hand as a reflecting element and on the other hand as electronic circuit or carrier of an electronic circuit. Suitable base layers are made of any material providing a sufficient reflectivity to re-direct light from the base layer towards the average emission direction and also providing a non-conducting environment or carrier for the printed electronics as part of the base layer. Suitable base layers may be made of polymer material or plastics. The term “average emission direction” denotes the emission direction, where the intensity maximum is achieved. Common LEDs emit light in a conical emission angle, where the intensity drops for larger angles. At a certain emission angle, the intensity of the emitted light has a maximum. The average emission direction is along the emission direction of light with maximum intensity. The base layer may be made of multiple layers, where one or more layers may comprise silver or aluminum to provide high reflectivity of a metal layer. In the multiple layer stack, the metal layers are covered with non-conducting layers. The production effort of thin base layer comprising e.g. three sub-layers is low due to the low layer thickness and the used materials. With such base layer providing an electronic circuit to operate the one or more LEDs attached to the base layer, a PCB can be avoided. A PCB commonly is a thick or massive layer. The avoided PCB enables to produce a LED light emitting device with smaller thickness across the layer stack, where the layer stack has a reduced number of layers. PCBs normally comprises several different layers. Subsequently the complexity of the layer stack according with the present disclosure is reduced resulting in an easier manufacturing process of this layer stack. The avoided production effort when not requiring a PCB also overcompensates a slightly increased production effort for a reflection layer as a multilayer.

The LED light emitting device described above enables also curved surface shapes easier than FR4 PCBs, in addition to a separate PCB. The base layer with printed electronics is cheaper than a separate flexible printed circuit (FPC) with polyimide, where polyimide also has difficulties for in-mold electronics (IME) implementation. The present solution has future implementation possibilities of IME with suitable substrate in ink used for printing electronics. Therefore, the above-described LED light emitting device can be manufactured more easily resulting in an improved production yield by using a layer stack with a reduced number of layers; here without a PCB layer avoiding at least three manufacturing steps related to the PCB layer.

In an embodiment the electronics are printed on top of a first side of the base layer directed towards the one or more LEDs. The printing may be carried out with different printing methods, e.g. screen printing, digital printing, inkjet printing, gravure etc. Screen printing is a printing technique where a mesh is used to transfer ink (or dye) onto the base layer, except in areas made impermeable to the ink by a blocking stencil. A blade or squeegee is moved across the screen to fill the open mesh apertures with ink, and a reverse stroke then causes the screen to touch the base layer momentarily along a line of contact. This causes the ink to wet the base layer and be pulled out of the mesh apertures as the screen springs back after the blade has passed. One material is printed at a time, so several screens can be used to produce a multi-material pattern on the base layer. Digital printing is a method of printing from a digital-based image directly to a variety of media. Inkjet printing is a type of computer printing that recreates a digital image by propelling droplets of ink onto the base layer. Gravure printing is a type of intaglio printing process, which involves engraving the image onto an image carrier. In gravure printing, the image is engraved onto a cylinder because, like offset printing and flexography, it uses a rotary printing press to transfer the to be printed material to the base layer. Printing the electronics on top of the base layer is a very easy process, which can be carried out very fast. The printing process according to the present disclosure uses a low temperature process allowing to use the base layer as substrate for the printed electronics.

In another embodiment the one or more LEDs are attached and electrically connected to the printed electronics of the base layer via conductive glue or an anisotropic adhesive. With these techniques, the LEDs can be fixed to the base layer is a reliable, simple and fast way. The dots of conductive glue or anisotropic adhesive can be applied via printing technology enabling to just apply the required amount of material not wasting material or spreading the material over areas, which should not be coated with conductive glue or anisotropic adhesive.

Further, the printed electronics may be made from conductive ink such as a liquid carrier comprising particles made of silver, copper, CNT etc. The particle density in the liquid matrix determines the conductivity properties and can be adjusted to the desired properties.

Still further, the base layer and the printed electronics may be covered by an overcoat protective layer in areas not covered by the LED or conductive glue. The overcoat protective layer is used to protect the printed electronics and any printed capacitive touch sensor patterns described later. The overcoat should preferably be applied to the upper side of the printed electronics and any printed capacitive touch sensor patterns. The overcoat layer protects the functionality of the printed electronics. It is especially advantageous to protect conductive ink. The overcoat layer may be made of a carbon material to at least protect covered layers against oxidation and/or mechanical abrasion. The requirements for the carbon coating layer e.g. depends on the type of used conductive ink for the printed electronics. The need for an overcoat depends on the type of ink/conductivity needed. If the printed electronics and any printed capacitive touch sensor patterns are formed from a non-oxidizing material, the overcoat protective layer is not necessarily needed.

In another embodiment the LED light emitting device is a display device. The display device may be a light source providing information to a user by illuminating the screen of the display. The display may provide capability to be operated as a touch screen be the user. In the present context, a display device is also understood to mean, for example, an illuminating device and a led matrix display. The main difference is the number of pixels used or displayable. An illuminating device has fewer individual pixels, for example a symbol as a warning or a lighting element. On the other hand, a display device has more pixels, so that more complex displays are possible.

In a further embodiment, the base layer has a second side directed away from the one or more LEDs, where printed capacitive touch sensor patterns are provided on top of the second side. The second side is the side opposite to the first side of the base layer, where the one or more LEDs are attached to. The resulting display device may be operated as a touch screen, with an easy handling. The base layer of the resulting display device, thus, provides three different functions, a reflectivity to re-direct parts of the emitted light, to provide an electronic circuit to operate the one or more LEDs and a capacitive touch sensor to provide a better handling of the display device by a user. This helps to improve production yield and further reduces the number of layers. This solution is especially advantageous for display devices, where high resolution detection of the touch screen functionality is not needed, e.g. a required resolution pitch is larger than 3 mm. Here, multilayer printing technology might be used to print the touch sensor pattern.

In another embodiment, the one or more LEDs are top and side emitting LEDs with average emission direction away from the base layer. In this case, the encapsulating layer is required only on top of the base layer and LEDs on the first side of the base layer followed by additional layer adjusting the light emission and light propagation to the outside of the LED light emitting device. This setup does not require a certain structuring of the base layer.

In another embodiment, the one or more LEDs are bottom emitting LEDs, where the base layer comprises a hole in an area of the base layer covered by the LED, where the LED emits light in an average emission direction through the hole of the base layer. Here the orientation of base layer, printed electronics and LEDs (eventually also printed capacitive touch sensor pattern) are just oppositely arranged compared to the setup with side and top emitting LEDs. The required hole might be filled with a transparent light guiding material, e.g. transparent plastic materials, to enable light emission from the bottom emitting LEDs. Here, both sides of the base layer might be covered with an encapsulation layer protecting both, the side, where the LEDs are attached as well as the opposite side, where the base layer and the hole are present to provide a smooth surface for additional layer of the layer stack in light emission direction. This set-up required structuring of the base layer without changing the setup of the remaining layer stack.

The present disclosure also provides a motor vehicle component with a light emitting device of the present disclosure. Also provided herein is a motor vehicle with such a motor vehicle component. The motor vehicle can be any kind of motor vehicle such as a car, truck, train, ship etc.

In addition, the present disclosure provides a method to manufacture a light emitting device of the present disclosure.

According to one embodiment, the method to manufacture a LED light emitting device with a layer stack comprising one or more LEDs according with the present disclosure, comprises the following steps of
providing a base layer with a reflective surface;
integrating printed electronics to the base layer providing at least signal and power lines to operate the one or more LEDs;
attaching one or more LEDs to the reflective surface of the base layer; and
covering the one or more LEDs and the base layer are covered by a encapsulation layer.

The printed electronics may be provided by screen printing, digital/ink jet printing, gravure etc. The printing step may comprise two or more sub-printing process steps to apply the printed material in subsequent printing processes. In particular, the base layer material is ink-process compatible. The base layer may be optionally shaped by cutting away certain areas of the base layer, e.g. areas not needed for the LED light emitting device. In an embodiment the integration step is carried out by printing the electronics on a first side of the base layer. The LEDs are attached to the base layer by a component pick on place process comprising several steps such as adhesive/solder place extraction and heat treatment. Isotropic or anisotropic conductive glue might be used as well as low temperature solder paste to attach the LEDs to the printed electronics. The LEDs are the main components of the LED light emitting device. Driver ICs and other electronic components of the LED light emitting device may be placed and connected in the same step. Further processes like thermo-forming, adhesive attachment and injection molding might be used to finish the LED light emitting device.

In another embodiment the printing step of the electronics comprises a curing step to cure the printed material of the electronic circuit. The curing can be done by heat and/or UV exposure. After curing subsequent layers can be applied onto the base layer and the printed electronics. The curing may be especially advantageous in case of multiple ink materials and multiple printing steps are required to print the electronics onto the base layer. Curing may be carried out at the end of the multiple printing process or after each printing step of the multiple printing process.

In another embodiment, the base layer with printed electronics may be cut to shape and remove non-necessary areas from the base layer. In case of using bottom emitting LEDs the preparation of holes into the base layer can be done in the same step. The holes may be provided with etching or punching.

In another embodiment, in case of using bottom emitting LEDs, this structuring step of providing a hole within the base layer in each area, where the bottom emitting LED will be attached to, is carried out prior to the step of attaching one or more LEDs to the base layer. The prepared holes might be filled with material of the encapsulation layer to provide a smooth surface for the LEDs to be applied.

In another embodiment the method further comprises the step of covering the printed electronics with an overcoat protective layer in areas not covered by the LED or conductive glue before applying the encapsulation layer.

The above listed embodiments can be used individually or in any combination to provide the device and the process in accordance with the invention. The combination of embodiments according to the scope of the invention may also deviate from the claim references as specified.

These and other aspects of the present disclosure will become more apparent from the following description of embodiments with reference to the Figures.

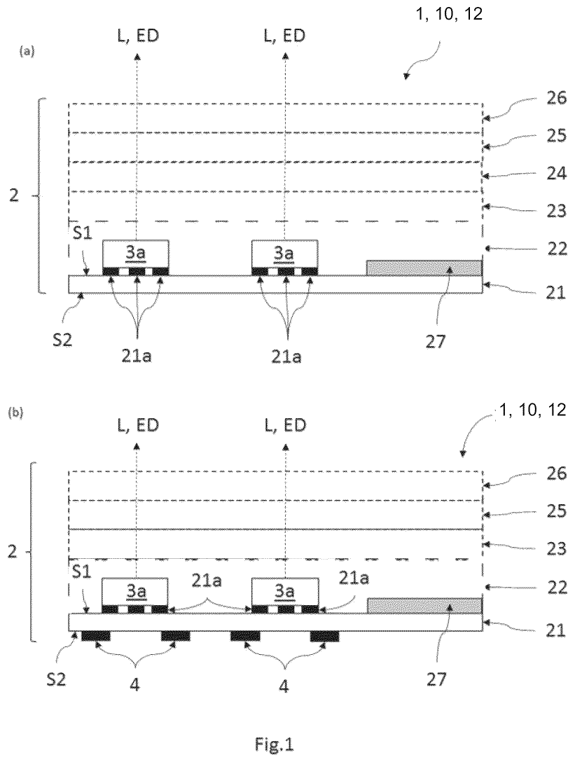

FIG. 1A and FIG. 1B show schematic views of LED illuminated reflectors 12 according to the present disclosure with LEDs 3 in the form of top/side emitting LEDs 3a, without and with a capacitive touch sensors 4 that may be provided in a variety of different patterns. The capacitive touch sensors 4 may be printed onto the reflector 21. FIG. 1A shows the LED illuminated reflector 12 without the capacitive touch sensors 4. FIG. 1B shows the LED illuminated reflector 12 with the capacitive touch sensors 4. The top/side emitting LEDs 3a emit light L have an average emission direction ED away from a base layer 21 (or a reflector 21), indicated by the dashed arrows. In the following, different embodiments of LED illuminated reflectors 12 according to the present disclosure are described.

Referring to FIGS. 1A-1B, the LED illuminated reflector 12 may include an optional layer stack 2 disposed onto two top/side LEDs 3a, wherein the LEDs 3a and the optional layer stack 2 are attached to the base layer 21. In this example, the top/side LEDs 3a and the base layer 21 may optionally be covered by an encapsulation layer 22. The base layer 21 (or reflector 21) may have printed electronics 21a configured to provide signals and power to the LEDs 3a via signal and power lines 21a to operate the top/side LEDs 3a. The electronics 21a are printed onto a first side S1 of the base layer 21 directed towards the top/side LEDs 3a. The top/side LEDs 3a are attached and electrically connected to the printed electronics 21a. The top/side LEDs 3a and the printed electronics 21a are attached to the base layer 21, in particular via conductive glue or an anisotropic adhesive. The printed electronics 21a may be made from conductive ink. The base layer 21, LEDs 3a, and printed electronics 21a may, but not necessarily, be covered by an optional overcoat protective layer 27 at least in areas not covered by the LED 3a or conductive glue.

Referring now to FIG. 1B, the LED illuminated reflector 12 shown in FIG. 1A may be provided with a, in particular printed, capacitive touch sensor pattern and/or a capacitive sensors 4 as shown in FIG. 1B to act as a display device 10. As shown in FIG. 1B, the base layer 21 has a second side S2 directed away from the LEDs 3a, wherein the, in particular printed, capacitive touch sensor pattern and/or the capacitive touch sensors 4 is/are provided onto, in particular on top of, a second side S2 to provide touch screen functionality with printed structures avoiding any further touch sensor electronic layers within the optional layer stack 2 e.g. in light emission direction above the optional encapsulation layer.

The optional layer stack 2 shown in FIGS. 1A-1B may comprise optional additional layers such as a diffuser layer 23, a touch sensor electronic layer 24, a carrier layer 25, and/or a protection or cosmetic layer 26.

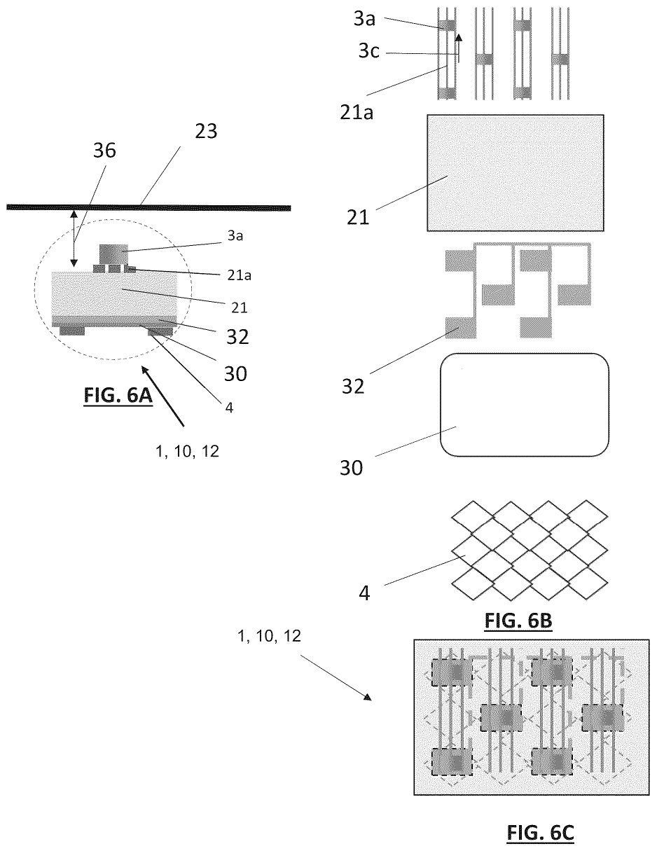

A diffuser (also called a light diffuser or optical diffuser) layer 23 may be made of any material that diffuses or scatters the light L in some manner to transmit soft light in transmission through the diffuser layer 23. The diffuser layer 23 provides an optimal appearance for a user. The diffuser layer 23 may use translucent material, for example ground glass, opal glass or greyed glass. The diffuser layer 23 may be disposed directly against the reflector and the reflector's components when the LEDs are mounted onto a lower surface S2 of the reflector 21. However, the diffuser layer 23 may also be disposed up to a maximum distance of approximately 15 mm when the LEDs are mounted onto a lower surface S2 of the reflector 21. (see element 36 in FIG. 6A representing the distance between reflector 21 and diffuser 23). In the event that the LEDs 3, 3a are mounted onto an upper surface S2 of the reflector 21, the diffuser layer 23 may be disposed at a minimum distance of approximately 0-3 mm from the reflector 21 up to a maximum distance of approximately 20 mm from the reflector 21. However, a distance between 10-15 mm (between the diffuser layer 23 and the reflector 21) provides an optimum aesthetic appearance.

It is also understood that a diffuser layer 23 may be implemented with proximity sensors (in lieu of or with touch sensors) wherein the proximity sensor(s) may be disposed between the optional diffuser layer 23 and the reflector 21 or base layer 21. In the event touch sensors are used, the touch sensors may be disposed onto the optional diffuser layer to enable a user's finger to actuate the touch sensors. Alternatively, the touch sensors may be disposed between the optional diffuser layer and the reflector 21 or base layer 21. However, in this alternative touch sensor arrangement, it is understood that there may, but not necessarily, be intervening layers between the “touch sensor layer and the diffuser” as well as between the “reflector and the touch sensor layer.”

In case no, in particular printed, capacitive touch sensor pattern and/or no capacitive touch sensors 4 is/are used, optionally on the base layer 21 or reflector 21, the optional carrier layer 25 may carry electronics with touch sensors 4 on top of the optional encapsulation layer 22 as an additional touch sensor electronic layer 24. It is understood that the carrier layer 25 may be a carrier with injection molded electronics or glued electronics. Still further, the carrier layer 25 may carry a protective or cosmetic layer 26 to provide a certain appearance of the LED light emitting device 1, 10 and/or the LED illuminated reflector 12 to a user. The cosmetic layer 26 will depend on where the device 1 will be used. In case of integrating the device 1 and/or the LED illuminated reflector 12 into an interior lining of a motor vehicle, the cosmetic layer 26 and/or the diffuser layer 23 may provide an appearance similar to the interior lining, but ample design alternatives are given.

Thus, the base layer 21 (and/or reflector 21) fulfills the function of a printed electronic substrate in addition to the function of a reflector, and in case of FIG. 1B even also the function of a capacitive touch sensor pattern substrate.

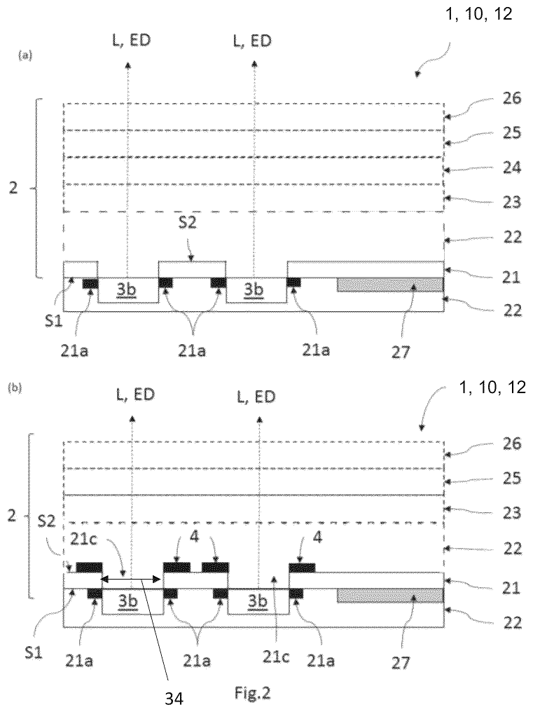

FIG. 2A and FIG. 2B show schematic views of LED light emitting devices 1 and/or LED illuminated reflectors 12 according to the present disclosure for bottom emitting LEDs 3b, with and without, in particular printed, capacitive touch sensor pattern and/or capacitive touch sensors 4, wherein optionally the sensors 4 may be provided in a pattern. FIG. 2A shows in particular the LED illuminated reflector 12 without the capacitive touch sensors 4, and FIG. 2B shows in particular the LED illuminated reflector 12 with the capacitive touch sensors 4. Most features of the embodiment of FIG. 2A correspond to the features already discussed with respect to FIG. 1A, and most features of the embodiment of FIG. 2B correspond to the features already discussed with respect to FIG. 1B, but in contrast to FIG. 1A and FIG. 1B, respectively, the LEDs 3 shown in FIG. 2A and FIG. 2B are bottom emitting LEDs 3b.

For each bottom emitting LED 3b, (i) the base layer 21 comprises a hole 21c, with the hole 21c being provided in an area of the base layer 21 covered by the LED 3b, and/or (ii) the reflector 21 defines an aperture 21c that is configured to substantially span the width 34 (see FIG. 2B) of the bottom LED 3b. The bottom LED 3b can emit light L in an average emission direction ED through the hole and/or aperture 21c of the base layer and/or the reflector 21, in particular as shown in FIGS. 2A-2B. The set-up and/or arrangements of the printed electronics 21a, the, in particular printed, capacitive touch sensor pattern and/or the capacitive touch sensors 4, and the overcoat protective layer 27 of FIGS. 2A-2B are inverted relative to the arrangement and/or set-up shown in FIGS. 1A-1B. In particular similar to the preceding embodiments, an optional encapsulation layer 22 may be applied to both sides S1, S2 of the base layer and/or reflector 21 in order to encapsulate both, the LEDs 3b, the printed electronics 21a and the optional printed capacitive touch sensor 4.

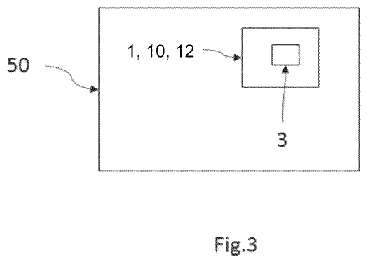

FIG. 3 shows a schematic view of the motor vehicle 50 comprising one or more LED light emitting devices 1 and/or LED illuminated reflectors 12 with LEDs 3 as described with reference to FIG. 1A to FIG. 2B. The motor vehicle can be any kind of motor vehicle such as cars, trucks, trains, ships etc. The LED light emitting device 1 and/or the LED illuminated reflector 12 can be integrated in any kind of vehicle part such as a dashboard, a rearview device, an interior lining and the like.

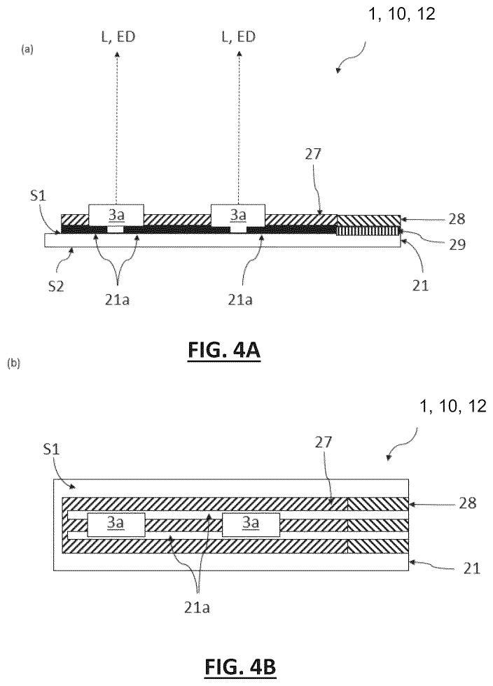

FIGS. 4A and 4B show a schematic view of a fifth embodiment of the present disclosure for top/side emitting LEDs 3a with a similar basic structure to embodiment example of FIG. 1. In this embodiment, the LED light emitting device 1 and/or the LED illuminated reflector 12 has an area of printed electronics, which are designed as contact pins 29. These contact pins 29 are used to supply power to the electrical loads of the dev LED light emitting device 1 and/or the LED illuminated reflector 12. The embodiment has an additional overcoat protective layer 27 on elements made from conductive ink as parts of the printed electronics of the base layer and/or reflector 21a. The embodiment further comprises of an optional carbon coat as an additional overcoat protective layer 28 on the contact pins 29. The overcoat layer protects 27 the functionality of the printed electronics 21a. The overcoat layer 28 is made of a carbon material to protect covered layers of the contact pins 29 against oxidation and mechanical abrasion.

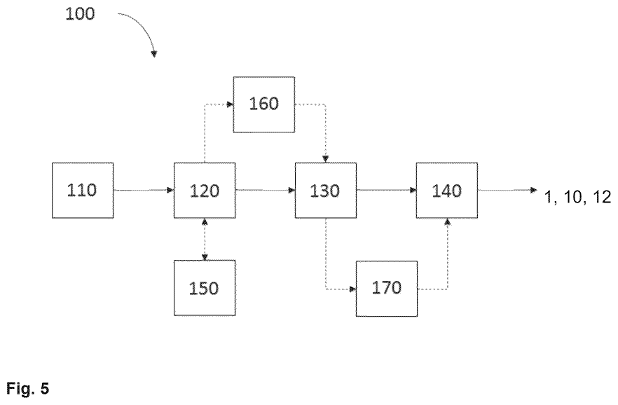

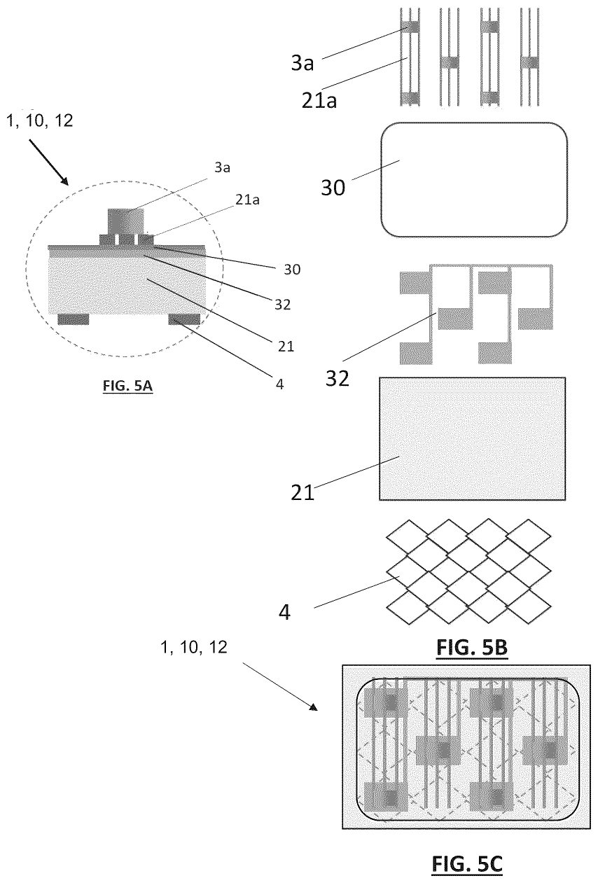

FIG. 5 shows an embodiment of a method 100 according to the present disclosure to manufacture a LED light emitting device 1 and/or a LED illuminated reflector 12 with a layer stack 2 comprising one or more LEDs 3 according to the present disclosure, e.g. as described with respect to any one of FIG. 1A to FIG. 1B. The method 100 comprises the following steps:
providing 110 a base layer and/or a reflector 21 with a reflective surface (S1);
integrating 120 printed electronics 21a to the base layer and/or the reflector 21 providing at least signal and power lines to operate the one or more LEDs 3;
attaching 130 the one or more LEDs 3 to the reflective surface (S1) of the base layer and/or the reflector 21; and
optionally covering 140 the one or more LEDs 3 and the base layer and/or reflector 21 at least by an encapsulation layer 22.

The integration step 120 might be carried out by printing the electronics 21a on a first side S1 of the base layer and/or reflector 21. The printing may be achieved by different printing methods, such as screen printing, gravure and the like. Ink-process-substrate compatibility is beneficial. Multiple ink materials and multiple printing steps may be used for printing the electronics. Further, the integration step 120 may comprise one or more heat and/or UV curing steps 150.

The base layer and/or reflector 21 may be cut into shape, and unnecessary areas may be removed. In case of using bottom emitting LEDs 3b, a structuring step 160 of providing a hole and/or an aperture 21c within the base layer and/or reflector 21 in each area, where the bottom emitting LED will be attached to, is carried prior to the step 130 of attaching the one or more LEDs 3 to the base layer and/or reflector 21.

The method 100 may comprise the step 170 of covering the printed electronics 21a with an overcoat protective layer 27 in areas not covered by the LED 3 or conductive glue before applying the optional encapsulation layer 22.

The attaching step 130 may include adhesive and/or solder place extraction and heat treatment. Isotopic or anisotropic conductive glue may be used as well as low temperature solder paste. The electronics to be integrated may comprise a driver IC.

In case touch sensor functions are to be embedded, a capacitive touch sensor pattern may be printed on the base layer and/or the reflector 21. Heat and/or UV curing may be done in the same step.

The method may be supplemented with further steps for integrating further layers, in particular to obtain a stack 2 as shown in FIG. 1A, 1B, 2A or 2B.

The stack 2 may take any desired geometry and the manufacturing method 100 may be adapted to the vehicle part into which the device 100 is to be integrated, with the base layer and/or reflector 21 being formed e.g. with a curved surface. The embodiments shown here are only examples of the present invention and must therefore not be understood as restrictive. Alternative embodiments considered by the skilled person are equally covered by the scope of protection of the present invention.

Referring now to FIGS. 5A-5B, another embodiment of the LED illuminated reflector 12 is shown wherein the reflector 21 includes a passivation/isolation layer 30 and a noise filter layer 32 on an upper surface S1 of the reflector 21. It is understood that the passivation/isolation layer 30 is provided to prevent a short from occurring between the power and signal lines 21a for the LEDs 3a. The noise filter layer 32 is configured to reduce the noise from the signals from LEDs 3a and the associated power and signal lines 21a (collectively referenced as the “LED components”) that would otherwise interfere with the performance of the touch sensors 4. The noise filter layer 32 may be printed onto the reflector 21 or base layer 21.

In this embodiment, at least one LED 3a and the associated power and signal lines 21a (collectively referenced as the “LED components”) are mounted onto the passivation/isolation layer 30, and the touch sensors 4 are mounted on the opposite lower surface S2 of the reflector 21. However, in order to actuate the touch sensors 4 (disposed on the lower surface S2) from the upper surface S1 from the upper surface S1 (by pressing the LED illuminated reflector 12 with a user's finger), the noise filter layer 32 must be limited to the regions that are in close proximity to the LED and the LED power/signal lines as shown in FIG. 5B—such that pressure applied from a user's finger will transfer to the sensors 4 that are located at the lower surface S2 of the reflector 21 or base layer 21. FIG. 5A provides a schematic cross-sectional view of the LED illuminated reflector 12. FIG. 5B is an expanded view of the various layers shown in FIG. 5A.

Referring now to FIGS. 6A-6B, another embodiment of the LED illuminated reflector 12 is shown wherein the reflector includes a passivation/isolation layer 30 and a noise filter layer on a lower surface S2 of the reflector. In this embodiment, at least one LED and the associated power and signal lines are mounted directly onto an upper surface S1 of the reflector, and the touch sensors 4 are mounted on the passivation/isolation layer at the lower surface S2 of the reflector 21. The activation/isolation layer 30 and the filter layer 32 in this embodiment provide the same function as indicated in the embodiment of FIGS. 5A-5B. However, in order to actuate the touch sensors 4 from the upper surface S1 (by pressing the LED illuminated reflector 12 with a user's finger), the noise filter layer 32 must be limited to the regions that are in close proximity (beneath) the LED and the LED power/signal lines as shown in FIGS. 6A-6B wherein the reflector 21 is disposed between the LED components and the noise filter layer 32—such that pressure applied from a user's finger will transfer to the sensors 4 that are located at the lower surface S2 of the reflector 21 or base layer 21. FIG. 6A provides a schematic cross-sectional view of the LED illuminated reflector 12 of this embodiment. FIG. 6B is an expanded view of the various layers shown in FIG. 6A. It is understood that the passivation/isolation layer is provided to prevent a short from occurring between the power and signal lines for the LEDS. The noise filter layer 32 is disposed between the touch sensors 4 and the LED 3a (and the LED's associated power/signal lines 21a).

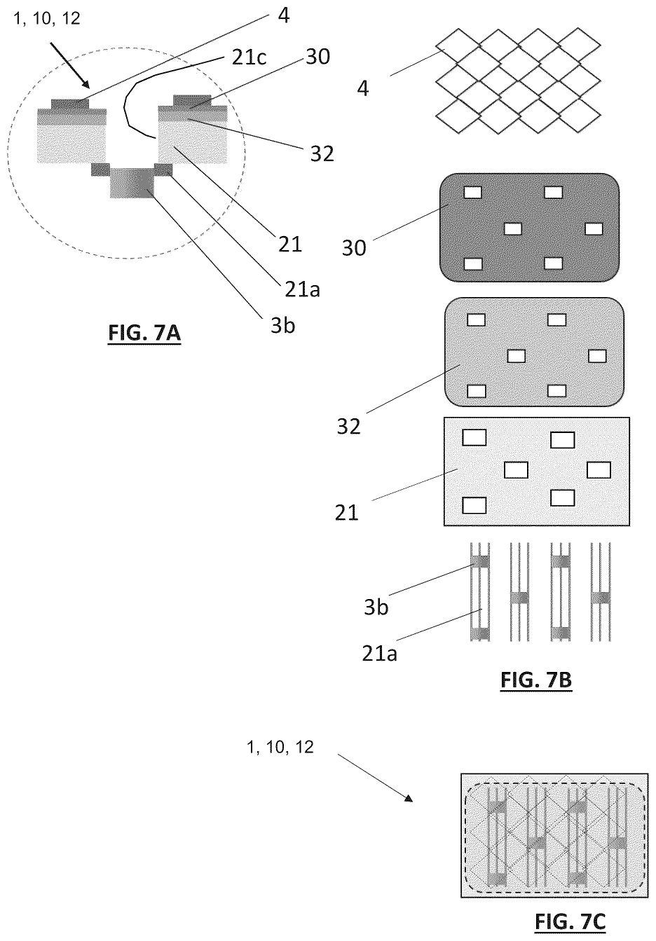

Referring now to FIGS. 7A-7B, another embodiment of the LED illuminated reflector 12 is shown wherein the LED components (LEDs 3b and LED power/signal lines 21a) are mounted on the lower surface S2 of the reflector 21 and wherein a passivation/isolation layer 30 and a noise filter layer 32 are disposed onto an upper surface S1 of the reflector 21. The activation/isolation layer 30 and the filter layer 32 in this embodiment provide the same function as indicated in the embodiment of FIGS. 5A-6B. In this embodiment, the reflector 21 defines an aperture 21c for each LED 3b so that the light from each LED 3b may be emitted out and away from the reflector 21 through the associated aperture 21c. The bottom LED 3b can emit light L in an average emission direction ED through the aperture 21c of the reflector 21 (see FIGS. 2A-2B). As shown, the noise filter layer 32 is disposed directly onto the upper surface S2 of the reflector and the passivation/isolation layer 30 is disposed onto the noise filter layer 32. As indicated, at least one LED 3b and the associated power and signal lines 21a are mounted directly onto a lower surface S2 of the reflector 21, and the touch sensors 4 are mounted on the passivation/isolation layer at the upper surface S1 of the reflector 21. Unlike the previous embodiments, the noise filter layer 32 will not interfere with the actuation of the touch sensors 4 given that the noise filter layer 32 is disposed below the touch sensors 4 (and the passivation/isolation layer 30) of FIGS. 7A-7B. Therefore, it is not required to have a “localized” noise filter layer 32 (as shown in FIGS. 5B and 6B). FIG. 7A provides a schematic cross-sectional view of the LED illuminated reflector 12 of this embodiment. FIG. 7B is an expanded view of the various layers shown in FIG. 6A. The noise filter layer 32 is disposed between the passivation/isolation layer 30 and the upper surface S1 of the reflector. Therefore, the noise filter layer 32 is configured to reduce the noise from the LED 3b and the LED signals 3c (see FIG. 5B) that could otherwise interfere with the performance of the touch sensors 4.

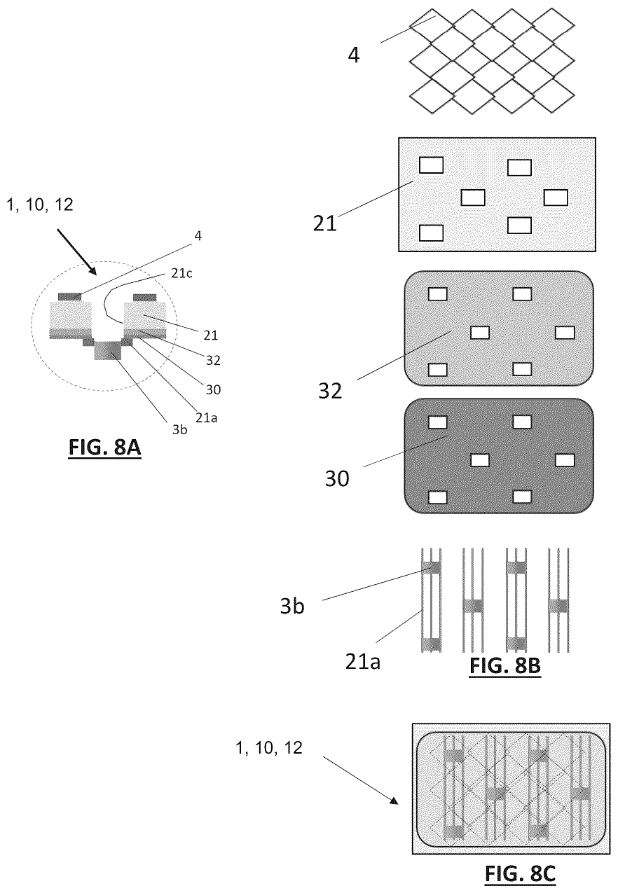

Referring now to FIGS. 8A-8B, another embodiment of the LED illuminated reflector 12 is shown wherein a passivation/isolation layer 30 and a noise filter layer 32 are disposed onto an lower surface S2 of the reflector 21, and wherein the LED components (LEDs 3b and LED power/signal lines 21a) are mounted at the lower surface S2 of the reflector 21 such that the passivation/isolation layer 30 and a noise filter layer 32 are disposed between the LED components and the reflector 21. The activation/isolation layer 30 and the filter layer 32 in this embodiment provide the same function as indicated in the embodiment of FIGS. 5A-7B. In the example shown in FIGS. 8A-8B, a noise filter layer 32 is disposed directly onto a lower surface S2 of the reflector 21, and the passivation/isolation layer 30 is disposed directly onto the noise filter layer 32. The LED components (LEDs 3b and LED power/signal lines 21a) are mounted on noise filter layer 32. In this embodiment, the reflector 21 defines an aperture 21c for each LED 3b so that the light from the each LED 3b may be emitted out and away from the reflector 21 through the aperture 21c. In this embodiment, the touch sensors 4 are mounted directly onto an upper surface S1 of the reflector 21. Therefore, unlike the previous embodiments in FIGS. 5A-6B, the noise filter layer 32 will not interfere with the actuation of the touch sensors 4 given that the noise filter layer 32 is disposed below the touch sensors 4 (and the reflector 21) of FIGS. 8A-8B. FIG. 8A provides a schematic cross-sectional view of the LED illuminated reflector 12 of this embodiment. FIG. 8B is an expanded view of the various layers shown in FIG. 8A.

With respect to the various embodiments of the present disclosure which include a noise filter layer 32 and/or an isolation layer 30 and/or the touch sensors 4, it is understood that each of the include a noise filter layer 32 and/or an isolation layer 30 and/or the touch sensors 4 are printed onto reflector or intervening layer during the assembly process. With respect to the isolation layer 30, it is understood that this layer may be an ink that is printed on.

It is also understood that the touch sensors 4 of the various embodiments of the present disclosure may be provided in a variety of different patterns and that the touch sensor pattern of FIGS. 5B, 6B, 7B, 8B is only one nonlimiting example. Moreover, it is understood that the touch sensors 4 of the present disclosure implement capacitive sensing such that the touch sensors 4 require a clean signal when a user's finger actuates (presses) on the touch sensor 4. In circumstances where the LED components are mounted on the upper surface S1 of the reflector 21 (see FIGS. 5A-6B), the touch sensors 4 are mounted at the opposite lower surface S2 of the reflector with the noise filter layer in between the LED components and the touch sensors 4. However, as noted, a continuous noise filter layer 32 (like that shown in FIGS. 7B and 8B) undesirably reduces pressure from an actuating finger to a touch sensor such that a touch sensor 4 may not be activated or triggered. Therefore, the noise filter layer 32 for top mounted LED components must be localized as shown in FIGS. 5A and 6A.

It is also understood that in the embodiments that implement an encapsulation layer wherein the LEDs are embedded in the encapsulation layer, the encapsulation layer may be configured to redirect light from one or more LED's within the encapsulation layer such that the light beam eventually exits the encapsulation layer in a particular direction. It is understood that the encapsulation layer may define reflective surfaces within the encapsulation layer such that the reflective surfaces redirect the light within the encapsulation layer and out of the encapsulation layer in a particular direction.

While at least multiple example, non-limiting embodiments have been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

### REFERENCE SIGN LIST

1 LED light emitting device
2 layer stack
3 LED(s)
3a top and side emitting LED
3b bottom emitting LED
4 printed capacitive touch sensor pattern
10 display device
12 LED illuminated reflector
21 base layer
21a printed electronics as part of the base layer
21c hole in the base layer
22 encapsulation layer
23 diffuser layer
24 touch sensor electronic layer
25 carrier layer
26 protection or cosmetic layer
27 overcoat protective layer
28 contact pins
29 carbon coat as an additional overcoat protective layer
50 motor vehicle
100 method to manufacture a LED light emitting device
110 providing a base layer
120 integrating printed electronics to the base layer, e.g. via printing
130 attaching one or more LEDs to the base layer
140 covering the LED(s) and the base layer by a encapsulation layer
150 UV curing step
160 providing a hole within the base layer
170 covering the printed electronics with an overcoat protective layer
ED average emission direction of the light emitted from the LED(s)
L light
S1 reflective surface of the base layer directed towards the LED(s)
S2 second side of the base layer directed away from the LED(s) (opposite to the first side)

1-23. (canceled)

24. A light emitting device with a layer stack, comprising:
a base layer with a reflective surface; and
one or more LEDs attached to the reflective surface of the base layer,
wherein the base layer comprises or is provided with printed electronics configured to provide signals and power to operate the one or more LEDs,
wherein the one or more LEDs comprise LEDs in form of bottom emitting LEDs, and
wherein the base layer comprises an aperture in an area of the base layer covered by a bottom emitting LED and the bottom emitting LED emits light in an average emission direction through the aperture of the base layer.

25. The device according to claim 24, further comprising at least one encapsulation layer, with the one or more LEDs and/or the base layer being covered by the encapsulation layer.

26. The device according to claim 24, wherein the printed electronics are printed on top of the reflective surface of the base layer directed towards the one or more LEDs, with the printed electronics comprising conductive ink.

27. The device according to claim 24, wherein the one or more LEDs, a driver IC and/or at least one electronic component are attached and electrically connected to the printed electronics of the base layer via conductive glue, or an anisotropic or isotopic adhesive, or a low temperature solder paste.

28. The device according to claim 27, wherein the base layer and the printed electronics are covered by an overcoat protective layer in areas not covered by the one or more LEDs, the driver IC and/or the at least one electronic component or the conductive glue, the anisotropic or isotopic adhesive or the temperature solder paste.

29. The device according to claim 24, wherein the base layer has a second side directed away from the one or more LEDs, and a printed capacitive touch sensor pattern is provided on top of the second side.

30. The device according to claim 24, wherein the one or more LEDs further comprise LEDs in form of top or top/side emitting LEDs with an average emission direction away from the base layer.

31. The device according to claim 24, wherein the layer stack further comprises one or more of
a diffuser layer comprising translucent material,
a touch sensor electronic layer,
a carrier layer, or
a protection or cosmetic layer.

32. The device according to claim 31, wherein the carrier layer is provided with injection molded electronics or glued electronics, with the electronics comprising touch sensors on top of the encapsulation layer or on top of the diffuser layer.

33. The device according to claim 24, wherein the device provides a display device and/or a touch screen.

34. A motor vehicle component comprising at least one device according to claim 24, wherein the motor vehicle component comprises a rear view device, a dashboard and/or an interior lining.

35. The motor vehicle component according to claim 34, wherein a protection or cosmetic layer and/or a surface geometry of a first and/or second surface of the base layer is configured to be adapted to a remaining motor vehicle component and/or the surrounding thereof.

36. A motor vehicle comprising at least one motor vehicle component according to claim 34.

37. A method for manufacturing a light emitting device, comprising:
providing a base layer with a reflective surface;
integrating printed electronics to the base layer configured for providing signals and power to operate the one or more LEDs; and
attaching one or more LEDs on the reflective surface of the base layer,
wherein the one or more LEDs comprise LEDs in form of bottom emitting LEDs, and
wherein the base layer comprises an aperture in an area of the base layer covered by a bottom emitting LED and the bottom emitting LED emits light in an average emission direction through the aperture of the base layer.

38. The method of claim 37, wherein
the one or more LEDs and/or base layer are covered by an encapsulation layer, and
wherein the integrating step comprises printing the printed electronics on the reflective surface of the base layer (21), in form of screen printing or gravure printing, and/or with multiple ink materials and/or multiple printing steps.

39. The method of claim 37, wherein the integrating step comprises one or more heat and/or UV curing steps.

40. The method of claim 37, wherein the base layer is formed with a curved reflective surface and/or second surface and/or is cut into shape.

41. The method of claim 37, wherein in case of using one or more bottom emitting LEDs, a structuring step for providing a hole and/or an aperture within the base layer in each area, where a bottom emitting LED is attached, is carried out prior to the attaching step.

42. The method of claim 41, wherein each hole and/or aperture is provided by etching or punching and/or is filled with material of an encapsulation layer to provide a smooth surface for the LEDs to be applied.

43. The method of claim 37, further comprising
covering the printed electronics with an overcoat protective layer in areas not covered by the one or more LEDs or conductive glue, before applying the encapsulation layer.

44. The method of claim 37, wherein the attaching step includes an adhesive and/or solder place extraction and/or a heat treatment.

45. The method of claim 37, further comprising
applying a diffusor layer, an electronic touch sensor layer, a carrier layer and/or a protection or cosmetic layer on the encapsulating layer.

46. The method of claim 37, further comprising embedding a touch sensor function to a layer stack, comprising
printing a capacitive touch sensor pattern on a second side of the base layer, or
applying a touch sensor electronic layer on a diffuser layer and/or on the reflective surface of the base layer.
